(19) United States
(12) Patent Application Publication
(10) Pub. No.: US 2022/0244593 A1
(43) Pub. Date: Aug. 4, 2022

(54) DISPLAY PANEL TRACE STRUCTURE, METHOD FOR FABRICATING SAME, AND DISPLAY PANEL THEREOF

(71) Applicant: TCL China Star Optoelectronics Technology Co., Ltd., Shenzhen (CN)

(72) Inventor: Hongyuan XU, Shenzhen (CN)

(21) Appl. No.: 16/622,914

(22) PCT Filed: Nov. 13, 2019
(86) PCT No.: PCT/CN2019/118205

§ 371 Date: Dec. 16, 2019

(30) Foreign Application Priority Data
Oct. 22, 2019 (CN) 201911004727.6

(51) Int. Cl. G02F 1/1362; G02F 1/1368

(52) U.S. Cl. CPC G02F 1/13629; G02F 1/136295; G02F 1/1368

(57) ABSTRACT

A trace structure provided by the present application includes a first metal layer including a plurality of first scan lines and a plurality of second scan lines, a second metal layer disposed on the first metal layer and corresponding to the first metal layer, the second metal layer including a plurality of first data lines and a plurality of second data lines, the first data lines disposed vertically, and the second data lines disposed horizontally, wherein each of the second data lines includes a plurality of gaps, and the first data lines are disposed in the plurality of gaps, respectively; wherein the second scan lines are connected to the first data lines in series, and the second data lines are connected to the first scan lines in series.

### FIELD OF INVENTION

The present application relates to the field of display panel manufacturing technologies, and in particular, to a display panel trace structure, a method for fabricating the same, and display panel thereof.

### BACKGROUND OF INVENTION

Liquid crystal displays (LCDs) are widely used flat panel displays, which mainly realizes screen display by modulating intensity of a backlight through a liquid crystal switch. Large-sized, high resolution, and high refresh rate are the current trends in the development of high-end thin film transistor-liquid crystal display (TFT-LCD) products. As a panel size becomes larger and larger, resolution becomes higher and higher, refresh frequency becomes faster and faster, and charging time of a thin film transistor is also shorter and shorter. Among them, the increase in the panel size is accompanied by extension of metal traces, resulting in a more serious capacitor delay.

Therefore, it is a technical problem to be solved by those skilled in the art to provide a new display panel trace structure to reduce the capacitor delay.

### SUMMARY OF INVENTION

The embodiments of the present application provide a display panel trace structure, a method for fabricating the display panel trace, and a display panel using the trace structure thereof, which the capacitor delay can be reduced.

An embodiment of the present application provides a display panel trace structure, including:

a first metal layer including a plurality of first scan lines and a plurality of second scan lines, the plurality of first scan lines disposed horizontally, and the plurality of second scan lines disposed vertically, wherein each of the plurality of second scan lines includes a plurality of intervals, and the plurality of first scan lines are disposed in the plurality of intervals, respectively; and

a second metal layer disposed on the first metal layer and corresponding to the first metal layer, the second metal layer including a plurality of first data lines and a plurality of second data lines, the plurality of first data lines disposed vertically, and the plurality of second data lines disposed horizontally, wherein each of the plurality of second data lines includes a plurality of gaps, and the plurality of first data lines are disposed in the plurality of gaps, respectively;

wherein the plurality of second scan lines are connected to the plurality of first data lines in series, and the plurality of second data lines are connected to the plurality of first scan lines in series.

In some embodiments, opposite portions of each of the first data lines corresponding to one of the intervals include a plurality of first protrusions and extended toward the adjacent second scan lines, and the plurality of first protrusions are connected to the adjacent second scan lines.

In some embodiments, opposite portions of each of the second data lines corresponding to one of the gaps include a plurality of second protrusions and extended toward the adjacent first scan lines, and the plurality of second protrusions are connected to the adjacent first scan lines.

In some embodiments, the display panel trace structure further including an insulating layer disposed on the first metal layer, wherein the insulating layer is provided with a plurality of via holes, the plurality of first protrusions are connected to the adjacent second scan lines through the plurality of via holes, and the plurality of second protrusions are connected to the adjacent first scan lines through the plurality of via holes, respectively.

In some embodiments, the display panel trace structure further including a plurality of thin film transistors connected with the plurality of first scan lines and the plurality of first data lines.

In some embodiments, shapes of the via holes are adapted to shapes of the first protrusions and shapes of the second protrusions.

In some embodiments, the first data lines, the second data lines, the first scan lines, and the second scan lines are made of copper wires.

An embodiment of the present application further provides method for fabricating a display panel trace, including:

disposing a plurality of second scan lines vertically with a plurality of intervals, and disposing a plurality of first scan lines in the plurality of intervals, respectively, to form a first metal layer; and

disposing a plurality of second data lines vertically with a plurality of gaps, and disposing a plurality first data lines in the plurality of gaps, respectively, to form a second metal layer;

wherein the second metal layer is disposed above and corresponding to the first metal layer;

the plurality of second scan lines are connected to the plurality of first data lines in series, and the plurality of second data lines are connected to the plurality of first scan lines in series.

In some embodiments, opposite portions of each of the first data lines corresponding to one of the intervals further include a plurality of first protrusions, opposite portions of each of the second data lines further include a plurality of second protrusions corresponding to one of the gaps, and the method further includes connecting the first data lines to the second scan lines through the plurality of first protrusions, and connecting the second data lines to the first scan lines through the plurality of first protrusions.

In some embodiments, the display panel trace further includes an insulating layer, the insulating layer provided with a plurality of via holes, and the method further includes connecting the plurality of first protrusions to the adjacent second scan lines through the plurality of via holes, and connecting the plurality of second protrusions to the adjacent first scan lines through the plurality of via holes.

In some embodiments, the display panel trace further includes a plurality of thin film transistors, and after connecting the second scan lines to the first data lines in series and connecting the second data lines to the first scan lines in series, the method further includes connecting the plurality of thin film transistors to the plurality of first scan lines and the plurality of first data lines, respectively.

In some embodiments, shapes of the via holes are adapted to shapes of the first protrusions and shapes of the second protrusions.

In some embodiments, the first data lines, the second data lines, the first scan lines, and the second scan lines are made of copper wires.

The embodiment of the present application further provides a display panel, which includes a trace structure, and the trace structure includes:

a first metal layer including a plurality of first scan lines and a plurality of second scan lines, the plurality of first scan lines disposed horizontally, and the plurality of second scan lines disposed vertically, wherein each of the plurality of second scan lines includes a plurality of intervals, and the plurality of first scan lines are disposed in the plurality of intervals, respectively; and

a second metal layer disposed on the first metal layer and corresponding to the first metal layer, the second metal layer including a plurality of first data lines and a plurality of second data lines, the plurality of first data lines disposed vertically, and the plurality of second data lines disposed horizontally, wherein each of the plurality of second data lines includes a plurality of gaps, and the plurality of first data lines are disposed in the plurality of gaps, respectively;

wherein the plurality of second scan lines are connected to the plurality of first data lines in series, and the plurality of second data lines are connected to the plurality of first scan lines in series.

In some embodiments, opposite portions of each of the first data lines corresponding to one of the intervals include a plurality of first protrusions and extended toward the adjacent second scan lines, and the plurality of first protrusions are connected to the adjacent second scan lines.

In some embodiments, opposite portions of each of the second data lines corresponding to one of the gaps include a plurality of second protrusions and extended toward the adjacent first scan lines, and the plurality of second protrusions are connected to the adjacent first scan lines.

In some embodiments, the display panel further including an insulating layer disposed on the first metal layer, wherein the insulating layer is provided with a plurality of via holes, the plurality of first protrusions are connected to the adjacent second scan lines through the plurality of via holes, and the plurality of second protrusions are connected to the adjacent first scan lines through the plurality of via holes.

In some embodiments, the display panel further including a plurality of thin film transistors connected with the plurality of first scan lines and the plurality of first data lines, respectively.

In some embodiments, shapes of the via holes are adapted to shapes of the first protrusions and shapes of the second protrusions.

In some embodiments, the first data lines, the second data lines, the first scan lines, and the second scan lines are made of copper wires.

### BRIEF DESCRIPTION OF FIGURES

In order to more clearly illustrate the technical solutions in the embodiments of the present application, the drawings used in the description of the embodiments will be briefly described below.

FIG. 1 is a schematic structural diagram of a display panel trace structure according to an embodiment of the present application.

FIG. 2 is a schematic structural diagram of a first metal layer of the display panel trace structure according to an embodiment of the present application.

FIG. 3 is a schematic structural diagram of a second metal layer of the display panel trace structure according to an embodiment of the present application.

FIG. 4 is a schematic structural diagram of a related display panel trace structure according to the embodiment of the present application.

FIG. 5 is another schematic structural diagram of the display panel trace structure according to the embodiment of the present application.

FIG. 6 is yet another schematic structural diagram of the display panel trace structure according to the embodiment of the present application.

FIG. 7 is a schematic flowchart showing a method for fabricating the display panel trace according to an embodiment of the present application.

### DETAILED DESCRIPTION OF EMBODIMENTS

The following content combines with the drawings and the embodiment for describing the present invention in detail. It is obvious that the following embodiments are only some embodiments of the present invention. For the skilled persons of ordinary skill in the art without creative effort, the other embodiments obtained thereby are still covered by the present invention.

The embodiment of the present application provides a display panel trace structure 100, a display panel trace, and a display panel. The display panel trace structure 100 will be described in detail below.

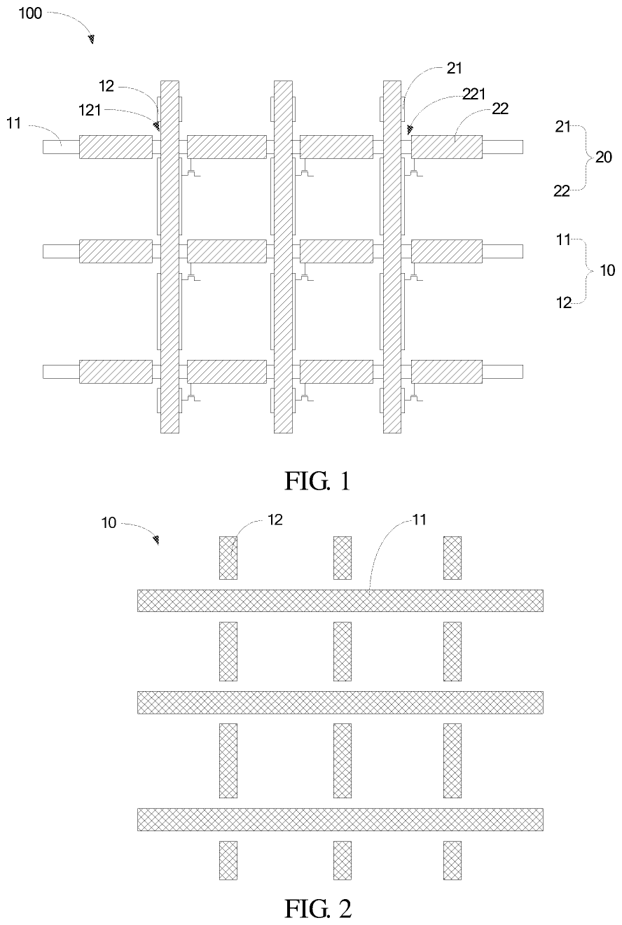

Referring to FIG. 1, FIG. 1 is a schematic structural diagram of a display panel trace structure 100 according to an embodiment of the present application. The display panel trace structure 100 provided by the embodiment of the present application includes a first metal layer 10 and a second metal layer 20. The second metal layer 20 is disposed on the first metal layer 10 and corresponds to the first metal layer 10.

Please refer to FIG. 2. FIG. 2 is a schematic structural diagram of the first metal layer 10 of the display panel trace structure 100 according to an embodiment of the present application. The first metal layer 10 includes a plurality of first scan lines 11 and a plurality of second scan lines 12, the plurality of first scan lines 11 are horizontally disposed, the plurality of second scan lines 12 are vertically disposed, each of the plurality of second scan lines 12 includes a plurality of intervals 121, and the plurality of first scan lines 11 are disposed in the plurality of intervals 121, respectively.

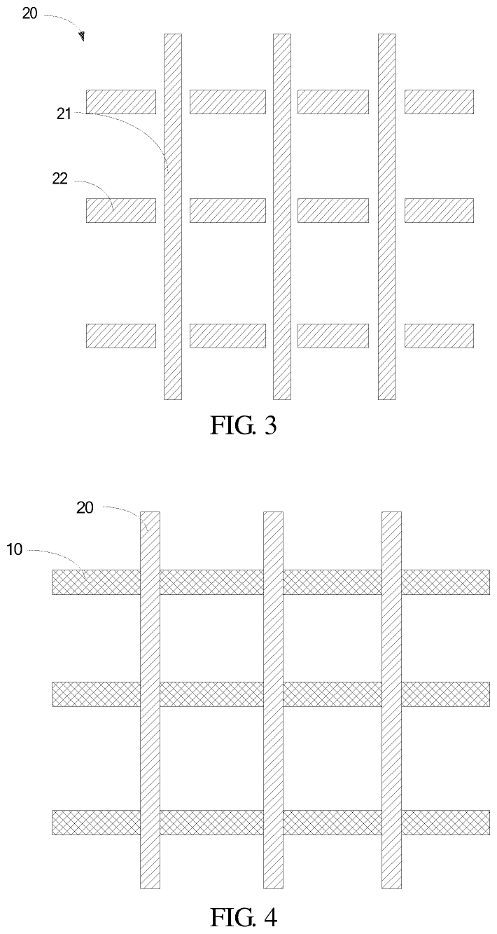

Please refer to FIG. 3. FIG. 3 is a schematic structural diagram of the second metal layer 20 of the display panel trace structure 100 according to an embodiment of the present application. The second metal layer 20 includes a plurality of first data lines 21 and a plurality of second data lines 22, the first data lines 21 are vertically disposed, the second data lines 22 are horizontally disposed, each of the plurality of second data lines 22 includes a plurality of gaps 221, and the plurality of first data lines 21 are disposed in the plurality of gaps 221, respectively. The plurality of second scan lines 12 are connected to the plurality of first data lines 21 in series, and the plurality of second data lines 22 are connected to the plurality of first scan lines 11 in series.

It should be noted that the data lines and the scan lines in the embodiments of the present application can made of copper wires. Data lines and scan lines made with a copper-wiring process can reduce impedance.

In a related embodiment, the display panel trace structure 100 fabricated by copper-wiring process is shown as FIG. 4. The associated trace structure 100 forms a plurality of pixel regions by staggering the horizontally disposed scan lines and the longitudinally disposed data lines. Generally, in the conventional art, such kind of structure is typically a single layer of metal traces. When the trace structure is applied to a large-sized display panels, the trace structure needs to be very thick (greater than 8000 angstrom) to meet the requirements. Since the trace structure 100 of the present application adopts double-layer, the copper thickness (less than 8000 angstrom) can also meet the requirements of large-sized display panels, which reduces the production cost and reduces the capacitor delay.

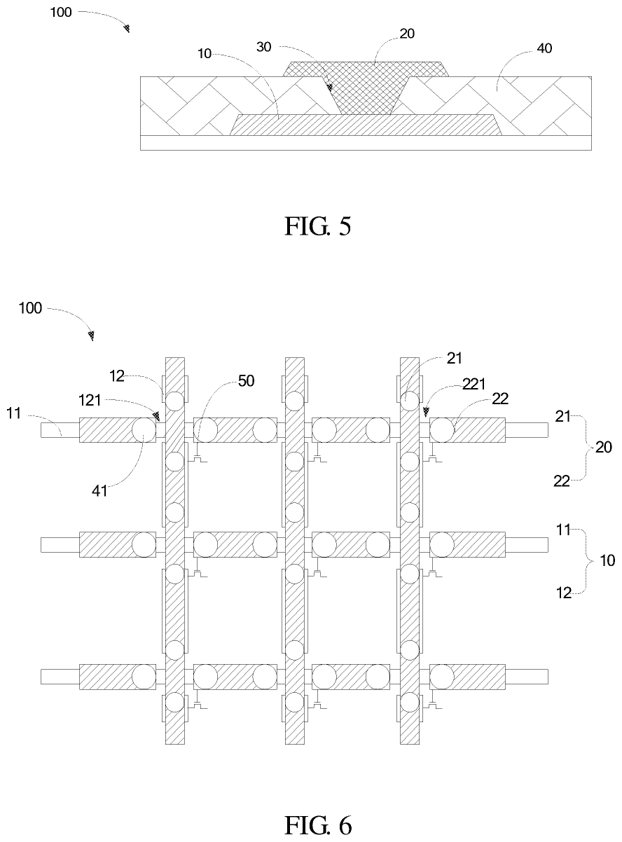

Referring to FIG. 5, FIG. 5 is another schematic structural diagram of the display panel trace structure 100 according to the embodiment of the present application. Meanwhile, opposite portions of each of the first data lines 21 corresponding to one of the intervals 121 include a plurality of first protrusions 30 and extended toward the adjacent second scan lines 12, and the plurality of first protrusions 30 are connected to the adjacent second scan lines. Moreover, opposite portions of each of the second data lines 22 corresponding to one of the gaps 221 include a plurality of second protrusions and extended toward the adjacent first scan lines 11, and the plurality of second protrusions are connected to the adjacent first scan lines 11.

It should be noted that shapes of the first protrusions 30 and shapes of the second protrusions can be same. Of course, the shapes of the first protrusions 30 and the shapes the second protrusions can also be different. In addition, the shapes of the protrusions are trapezoidal. The protrusions are gradually narrowed from the first data lines 21 toward the adjacent second scan lines 12. It will be appreciated that the first protrusions and the second protrusions can also be other shapes. In the embodiment of the present application, the specific shapes of the first protrusions 30 and the second protrusions are not described in detail.

Therebetween, an insulating layer 40 is disposed on the first metal layer 10, and the insulating layer 40 is provided with a plurality of via holes 41. The plurality of first protrusions 30 are connected to the adjacent second scan lines 12 through the plurality of via holes 41, and the plurality of second protrusions are connected to the adjacent first scan lines 11 through the plurality of via holes 41, respectively.

It should be noted that the shapes of the via holes 41 in the embodiment of the present application are adapted to the shapes of the first protrusions 30 and the shapes of the second protrusions.

Please refer to FIG. 6. FIG. 6 is yet another schematic structural diagram of the display panel trace structure 100 according to the embodiment of the present application. The trace structure 100 further includes a plurality of thin film transistors 50 that connected to the plurality of first scan lines 11 and the plurality of first data lines 21.

It should be noted that the thin film transistors 50 control the rotation of the liquid crystal by changing voltages so that the liquid crystal generates a picture. In the embodiment of the present application, since the second scan lines 12 are connected to the first data lines 21 in series, the second data lines 22 are connected to the first scan lines 11 in series. Therefore, the capacitor delay is reduced and to meet the requirements of large-sized panels.

In the embodiment of the present application, the display panel trace structure 100 includes the first metal layer 10 and the second metal layer 20, and the first metal layer 10 includes the plurality of first scan lines 11 and the plurality of second scan lines 12, and the plurality of first scan lines 11 are horizontally disposed, the plurality of second scan lines 12 are vertically disposed. Each of the plurality of second scan lines 12 includes a plurality of intervals 121, and the plurality of first scan lines 11 are disposed in the plurality of intervals 121, respectively. The second metal layer 20 is disposed on the first metal layer 10 and corresponds to the first metal layer 10. The second metal layer 20 includes the plurality of first data lines 21 and the plurality of second data lines 22, the plurality of first data lines 21 are disposed vertically, and the plurality of second data lines 22 are disposed horizontally. Each of the plurality of second data lines 12 includes the plurality of gaps 221, and the plurality of first data lines are disposed in the plurality of gaps 221, respectively. The plurality of second scan lines 12 are connected to the plurality of first data lines 21 in series, and the plurality of second data lines 22 are connected to the plurality of first scan lines 11 in series. Since the trace structure 100 the present application adopts double-layer, the copper thickness is reduced, which is a reduction in production cost, and at the same time, the capacitor delay can be reduced to meet the requirements of large-sized and high-standard panels.

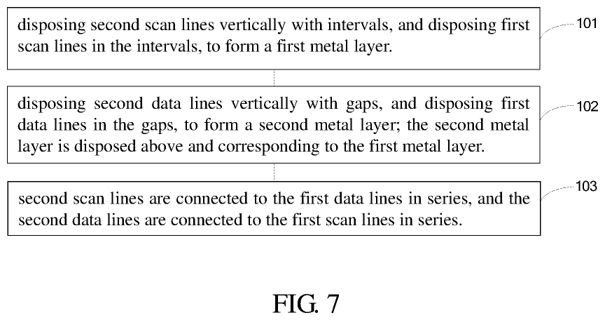

Please refer to FIG. 7. FIG. 7 is a schematic flowchart showing a method for fabricating the display panel trace according to the embodiment of the present application. The embodiment of the present application provides the method for fabricating the display panel trace, including:

101, disposing a plurality of second scan lines vertically with a plurality of intervals, and disposing a plurality of first scan lines in the plurality of intervals, respectively, to form a first metal layer.

102, disposing a plurality of second data lines vertically with a plurality of gaps, and disposing a plurality first data lines in the plurality of gaps, respectively, to form a second metal layer; wherein the second metal layer is disposed above and corresponding to the first metal layer.

103, the plurality of second scan lines are connected to the plurality of first data lines in series, and the plurality of second data lines are connected to the plurality of first scan lines in series.

Therebetween, the method further includes connecting the first data lines to the second scan lines through the plurality of first protrusions, and connecting the second data lines to the first scan lines through the plurality of first protrusions.

Therebetween, the method further includes connecting the plurality of first protrusions to the adjacent second scan lines through the plurality of via holes of the insulating layer, and connecting the plurality of second protrusions to the adjacent first scan lines through the plurality of via holes of the insulating layer.

Therebetween, after connecting the second scan lines to the first data lines in series and connecting the second data lines to the first scan lines in series, the method further includes connecting the plurality of thin film transistors to the plurality of first scan lines and the plurality of first data lines, respectively.

The embodiment of the present application further provides a display panel, which includes the display panel trace structure of the described above. Since the trace structure of the display panel has been described in detail in the above embodiment. Here, the description is not repeated in detail.

The display panel trace structure, the method for fabricating the display panel trace, and the display panel using the trace structure thereof provided by the embodiments of the present application are provided above. Embodiments of the present invention have been described, but not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A display panel trace structure, comprising:
a first metal layer comprising a plurality of first scan lines and a plurality of second scan lines, the plurality of first scan lines disposed horizontally, and the plurality of second scan lines disposed vertically, wherein each of the plurality of second scan lines comprises a plurality of intervals, and the plurality of first scan lines are disposed in the plurality of intervals, respectively; and
a second metal layer disposed on the first metal layer and corresponding to the first metal layer, the second metal layer comprising a plurality of first data lines and a plurality of second data lines, the plurality of first data lines disposed vertically, and the plurality of second data lines disposed horizontally, wherein each of the plurality of second data lines comprises a plurality of gaps, and the plurality of first data lines are disposed in the plurality of gaps, respectively;
wherein the plurality of second scan lines are connected to the plurality of first data lines in series, and the plurality of second data lines are connected to the plurality of first scan lines in series.

2. The display panel trace structure of claim 1, wherein opposite portions of each of the first data lines corresponding to one of the intervals comprise a plurality of first protrusions and extended toward the adjacent second scan lines, and the plurality of first protrusions are connected to the adjacent second scan lines.

3. The display panel trace structure of claim 2, wherein opposite portions of each of the second data lines corresponding to one of the gaps comprise a plurality of second protrusions and extended toward the adjacent first scan lines, and the plurality of second protrusions are connected to the adjacent first scan lines.

4. The display panel trace structure of claim 3, further comprising an insulating layer disposed on the first metal layer, wherein the insulating layer is provided with a plurality of via holes, the plurality of first protrusions are connected to the adjacent second scan lines through the plurality of via holes, and the plurality of second protrusions are connected to the adjacent first scan lines through the plurality of via holes, respectively.

5. The display panel trace structure of claim 4, further comprising a plurality of thin film transistors connected with the plurality of first scan lines and the plurality of first data lines.

6. The display panel trace structure of claim 4, wherein shapes of the via holes are adapted to shapes of the first protrusions and shapes of the second protrusions.

7. The display panel trace structure of claim 1, wherein the first data lines, the second data lines, the first scan lines, and the second scan lines are made of copper wires.

8. A method for fabricating a display panel trace, comprising:
disposing a plurality of second scan lines vertically with a plurality of intervals, and disposing a plurality of first scan lines in the plurality of intervals, respectively, to form a first metal layer; and
disposing a plurality of second data lines vertically with a plurality of gaps, and disposing a plurality first data lines in the plurality of gaps, respectively, to form a second metal layer;
wherein the second metal layer is disposed above and corresponding to the first metal layer;
the plurality of second scan lines are connected to the plurality of first data lines in series, and the plurality of second data lines are connected to the plurality of first scan lines in series.

9. The method for fabricating the display panel trace of claim 8, wherein opposite portions of each of the first data lines corresponding to one of the intervals further comprise a plurality of first protrusions, opposite portions of each of the second data lines further comprise a plurality of second protrusions corresponding to one of the gaps, and the method further comprises connecting the first data lines to the second scan lines through the plurality of first protrusions, and connecting the second data lines to the first scan lines through the plurality of first protrusions.

10. The method for fabricating the display panel trace of claim 8, wherein the display panel trace further comprises an insulating layer, the insulating layer provided with a plurality of via holes, and the method further comprises connecting the plurality of first protrusions to the adjacent second scan lines through the plurality of via holes, and connecting the plurality of second protrusions to the adjacent first scan lines through the plurality of via holes.

11. The method for fabricating the display panel trace of claim 9, wherein the display panel trace further comprises a plurality of thin film transistors, and after connecting the second scan lines to the first data lines in series and connecting the second data lines to the first scan lines in series, the method further comprises connecting the plurality of thin film transistors to the plurality of first scan lines and the plurality of first data lines, respectively.

12. The method for fabricating the display panel trace of claim 10, wherein shapes of the via holes are adapted to shapes of the first protrusions and shapes of the second protrusions.

13. The method for fabricating the display panel trace of claim 8, wherein the first data lines, the second data lines, the first scan lines, and the second scan lines are made of copper wires.

14. A display panel, comprising a trace structure, the trace structure comprising:
a first metal layer comprising a plurality of first scan lines and a plurality of second scan lines, the plurality of first scan lines disposed horizontally, and the plurality of second scan lines disposed vertically, wherein each of the plurality of second scan lines comprises a plurality of intervals, and the plurality of first scan lines are disposed in the plurality of intervals, respectively; and
a second metal layer disposed on the first metal layer and corresponding to the first metal layer, the second metal layer comprising a plurality of first data lines and a plurality of second data lines, the plurality of first data lines disposed vertically, and the plurality of second data lines disposed horizontally, wherein each of the plurality of second data lines comprises a plurality of gaps, and the plurality of first data lines are disposed in the plurality of gaps, respectively;
wherein the plurality of second scan lines are connected to the plurality of first data lines in series, and the plurality of second data lines are connected to the plurality of first scan lines in series.

15. The display panel of claim 14, wherein opposite portions of each of the first data lines corresponding to one of the intervals comprise a plurality of first protrusions and extended toward the adjacent second scan lines, and the plurality of first protrusions are connected to the adjacent second scan lines.

16. The display panel of claim 15, wherein opposite portions of each of the second data lines corresponding to one of the gaps comprise a plurality of second protrusions and extended toward the adjacent first scan lines, and the plurality of second protrusions are connected to the adjacent first scan lines.

17. The display panel of claim 16, further comprising an insulating layer disposed on the first metal layer, wherein the insulating layer is provided with a plurality of via holes, the plurality of first protrusions are connected to the adjacent second scan lines through the plurality of via holes, and the plurality of second protrusions are connected to the adjacent first scan lines through the plurality of via holes.

18. The display panel of claim 17, further comprising a plurality of thin film transistors connected with the plurality of first scan lines and the plurality of first data lines, respectively.

19. The display panel of claim 17, wherein shapes of the via hole are adapted to shapes of the first protrusions and shapes of the second protrusions.

20. The display panel of claim 14, wherein the first data lines, the second data lines, the first scan lines, and the second scan lines are made of copper wires.
